(19) United States
(12) Patent Application Publication
(10) Pub. No.: US 2018/0254359 A1
(43) Pub. Date: Sep. 6, 2018

(54) SOLAR CELL AND SOLAR CELL MANUFACTURING METHOD

(71) Applicant: MITSUBISHI ELECTRIC CORPORATION, Chiyoda-ku, Tokyo (JP)

(72) Inventor: Hayato KOHATA, Tokyo (JP)

(73) Assignee: MITSUBISHI ELECTRIC CORPORATION, Chiyoda-ku, Tokyo (JP)

(21) Appl. No.: 15/754,014

(22) PCT Filed: Aug. 28, 2015
(86) PCT No.: PCT/JP2015/074526

§ 371 Date: Feb. 21, 2018

(51) Int. Cl. H01L 31/0224; H01L 31/18

(52) U.S. Cl. CPC H01L 31/022433; H01L 31/1868; H01L 31/1804; H01L 31/022441

(57) ABSTRACT

A solar cell includes an n-type semiconductor substrate having a p-n junction and a back-surface side impurity-diffusion layer. The back-surface side impurity-diffusion layer is formed on a light-receiving surface of the semiconductor substrate or surface layer on a back-surface side opposite to the light-receiving surface, and has back-surface side high-concentration impurity-diffusion layers each of which contains an n-type or p-type impurity element at a first concentration and a back-surface side low-concentration impurity-diffusion layer which contains an impurity element of the same conductivity type as a conductivity type of the back-surface side high-concentration impurity-diffusion layers at a second concentration lower than the first concentration. The solar cell includes back-surface first electrodes formed at locations on a back-surface of the semiconductor substrate and electrically connected to the back-surface side high-concentration impurity-diffusion layers and back-surface second electrodes electrically connecting the back-surface first electrodes while being separated from the back-surface side impurity-diffusion layer.

### FIELD

The present invention relates to a solar cell having a selective diffusion layer structure and a method of manufacturing the solar cell.

### BACKGROUND

Conventionally, as a technique for achieving high photoelectric conversion efficiency of a solar cell using an n-type silicon substrate, Patent Literature 1 discloses a technique for improving photoelectric conversion efficiency based on a double-sided selective diffusion layer structure. In Patent Literature 1, a high-concentration p-type diffusion region and a low-concentration p-type diffusion region are formed on a front surface side of an n-type silicon substrate, and a high-concentration n-type diffusion region and a low-concentration n-type diffusion region are formed on a back surface side of the n-type silicon substrate. There is disclosed a solar cell in which a front surface electrode composed of a grid electrode and a bus bar electrode is formed on the high-concentration p-type diffusion region on the front surface side, and a back surface electrode composed of a grid electrode and a bus bar electrode is formed on the high-concentration n-type diffusion region on the back surface side.

When an n-type substrate is used as a solar cell substrate, an emitter is a p+ diffusion layer. Here, by using a silver-aluminum (Ag—Al) paste as a material of an electrode connected to the p+ diffusion layer, a good contact between the p+ diffusion layer and the electrode can be formed even in a diffusion layer having a relatively low concentration, whose p-type impurity concentration in the p+ diffusion layer is about 5×10¹⁹ atoms/cm³ or less. For this reason, a high photoelectric conversion efficiency of 20% or more can be achieved without employing a selective diffusion layer structure in which a high-concentration impurity diffusion layer is formed only in a region under an electrode.

On the other hand, regarding an n+ diffusion layer (Back Surface Field: BSF) on a back surface of the solar cell substrate, it is difficult to form a sufficiently-low contact resistance between the n+ diffusion layer and an electrode with respect to the n+ diffusion layer whose n-type impurity concentration is about 1×10¹⁹ atoms/cm³ or less. For this reason, usually, an impurity concentration of about 1×10²⁰ atoms/cm³ is required in the n+ diffusion layer on the back surface. Hereinafter, regarding an impurity concentration, “1×10¹⁹ atoms/cm³” may be expressed as “19th power”. Hereinafter, regarding an impurity concentration, “1×10²⁰ atoms/cm³” may be expressed as “20th power”. An impurity concentration of the 19th power means that 1×10¹⁹ impurity molecules are contained in a volume of one cubic centimeter.

Since the n+ diffusion layer having a low impurity concentration in the order of the 19th power has a weak electric field effect, recombination in the n+ diffusion layer due to a defect at an interface where an electrode is formed is significant, and thereby characteristics deterioration is caused. However, in the n+ diffusion layer having an impurity concentration in a 20th power range, even if a passivation film is formed on the back surface side of the solar cell substrate, that is, on the n+ diffusion layer, recombination in the n+ diffusion layer is significant, thereby resulting in preventing the photoelectric conversion efficiency from being maximized. In particular, in order to obtain a high photoelectric conversion efficiency of 21% or more, an n+ diffusion layer having an impurity concentration in the order of the 19th power is preferably formed, and a selective diffusion layer structure is needed to be formed.

In a solar cell in which an n-type substrate is used as a solar cell substrate and a passivation film is provided on a back surface side thereof, it is important to improve a passivation property by using a back surface selective diffusion layer structure. In order to optimize the passivation property on the back surface side of the solar cell substrate, it is important to reduce an area ratio of a high-concentration impurity diffusion layer region in an impurity diffusion layer on the back surface of the solar cell substrate and to reduce a contact region between an electrode and the impurity diffusion layer. Manufacturing steps for the selective diffusion layer structure and the electrode are as follows.

First, a selective diffusion layer structure is formed. A doping paste is printed on a back surface of an n-type substrate, for example, and heat-treated to partially form a high-concentration diffusion layer region. In addition, a low-concentration impurity diffusion layer region is formed on the back surface of the n-type substrate by gas phase thermal diffusion. Next, an electrode is formed on the high-concentration diffusion layer region. Here, when the electrode is brought into contact with the low-concentration impurity diffusion layer, recombination in the contact portion is increased, whereas the low-concentration impurity diffusion layer has a weak electric field effect, and the contact between the low-concentration impurity diffusion layer and the electrode has a significant influence, thereby leading to characteristics deterioration. For this reason, it is necessary to design an electrode such that the electrode does not protrude from the high-concentration diffusion region.

Screen printing, which is cost-effective, is usually used for electrode formation. In screen printing, since an electrode material paste containing metal is extruded from a mask opening and a semiconductor substrate is coated with the electrode material paste, a high efficiency in the use of material is obtained. In addition, by adding a glass or ceramic component to the electrode material paste, the passivation film can be fired through in a subsequent firing step and a metal material and a silicon surface can be brought into contact with each other. Consequently, an expensive contact hole opening process is unnecessary.

### CITATION LIST

### Patent Literature

Patent Literature 1: Japanese Patent Application Laid-Open No. 2012-54457

### SUMMARY

### Technical Problem

However, in a case of forming a long slimline grid electrode in screen printing, a print width is allowed for a thinning process is about 30 μm to 100 μm, and it is difficult to make sufficient thinning. In addition, in view of a problem of expansion/contraction of a mask or a problem of alignment accuracy, it is necessary to form a high-concentration diffusion layer wider than an electrode width.

On the other hand, high-concentration impurity diffusion regions cause deterioration of characteristics except for electrode formation regions. For this reason, in order to increase photoelectric conversion efficiency of a solar cell, it is necessary to reduce the high-concentration impurity diffusion regions, but since thinning of grid electrodes is difficult, there is a limit in reduction of the high-concentration impurity diffusion regions. In addition, since it is difficult to thin grid electrodes, there is a similar limit in reduction of contact regions between a low-concentration impurity diffusion layer and electrodes.

The present invention has been made in view of the above circumstances, and its object is to provide a solar cell having a selective diffusion layer structure and being able to achieve a high photoelectric conversion efficiency.

### Solution to Problem

In order to solve the above-mentioned problems and achieve the object, the present invention provides a solar cell comprising: an n-type semiconductor substrate having a p-n junction; an impurity diffusion layer which is formed on a light-receiving surface of the semiconductor substrate or a surface layer on a back surface side opposite to the light-receiving surface, and has a first impurity diffusion layer containing an n-type or p-type impurity element at a first concentration and a second impurity diffusion layer containing an impurity element of the same conductivity type as a conductivity type of the first impurity diffusion layer at a second concentration lower than the first concentration; first electrodes which are formed at a number of locations on a surface of the semiconductor substrate on which the impurity diffusion layer has been formed, each electrically connected to the first impurity diffusion layer; and a second electrode which electrically connects the first electrodes while being separated from the impurity diffusion layer.

### Advantageous Effects of Invention

The solar cell according to the present invention has an effect that a solar cell having a selective diffusion layer structure and being able to achieve a high photoelectric conversion efficiency can be realized.

### BRIEF DESCRIPTION OF DRAWINGS

FIG. 1 is a top view of a solar cell according to a first embodiment of the present invention, as viewed from a light-receiving surface side thereof.

FIG. 2 is a bottom view of the solar cell according to the first embodiment of the present invention, as viewed from a back surface side opposite to the light-receiving surface.

FIG. 3 is an enlarged view illustrating the back surface side of the solar cell according to the first embodiment of the present invention.

FIG. 4 is a cross-sectional view of a main part of the solar cell according to the first embodiment of the present invention, and is a cross-sectional view taken along a line A-A in FIG. 3.

FIG. 5 is a cross-sectional view of a main part of the solar cell according to the first embodiment of the present invention, and is a cross-sectional view taken along a line B-B in FIG. 3.

FIG. 6 is a flowchart for explaining a procedure of a method of manufacturing the solar cell according to the first embodiment of the present invention.

FIG. 7 is a main-part cross-sectional view for explaining the method of manufacturing the solar cell according to the first embodiment of the present invention.

FIG. 8 is a main-part cross-sectional view for explaining the method of manufacturing the solar cell according to the first embodiment of the present invention.

FIG. 9 is a main-part cross-sectional view for explaining the method of manufacturing the solar cell according to the first embodiment of the present invention.

FIG. 10 is a main-part cross-sectional view for explaining the method of manufacturing the solar cell according to the first embodiment of the present invention.

FIG. 11 is a main-part cross-sectional view for explaining the method of manufacturing the solar cell according to the first embodiment of the present invention.

FIG. 12 is a main-part cross-sectional view for explaining the method of manufacturing the solar cell according to the first embodiment of the present invention.

FIG. 13 is a main-part cross-sectional view for explaining the method of manufacturing the solar cell according to the first embodiment of the present invention.

FIG. 14 is a main-part cross-sectional view for explaining the method of manufacturing the solar cell according to the first embodiment of the present invention.

FIG. 15 is a main-part cross-sectional view for explaining the method of manufacturing the solar cell according to the first embodiment of the present invention.

FIG. 16 is a top view of a solar cell according to a second embodiment of the present invention, as viewed from a light-receiving surface side thereof.

FIG. 17 is an enlarged view illustrating the light-receiving surface side of the solar cell according to the second embodiment of the present invention.

FIG. 18 is a cross-sectional view of a main part of the solar cell according to the second embodiment of the present invention, and is a cross-sectional view taken along a line C-C in FIG. 17.

FIG. 19 is a cross-sectional view of a main part of the solar cell according to the second embodiment of the present invention, and is a cross-sectional view taken along a line D-D in FIG. 17.

FIG. 20 is a flowchart for explaining a procedure of a method of manufacturing the solar cell according to the second embodiment of the present invention.

FIG. 21 is a main-part cross-sectional view for explaining the method of manufacturing the solar cell according to the second embodiment of the present invention.

FIG. 22 is a main-part cross-sectional view for explaining the method of manufacturing the solar cell according to the second embodiment of the present invention.

FIG. 23 is a main-part cross-sectional view for explaining the method of manufacturing the solar cell according to the second embodiment of the present invention.

### DESCRIPTION OF EMBODIMENTS

Hereinafter, a solar cell and a method of manufacturing the solar cell according to embodiments of the present invention will be described in detail with reference to the drawings. The present invention is not necessarily limited to the following description and can be appropriately changed without departing from the gist of the present invention. In the drawings used below, scales of members may be different from the actual scales thereof for the sake of easy understanding. The same applies to scales among the drawings.

### First Embodiment

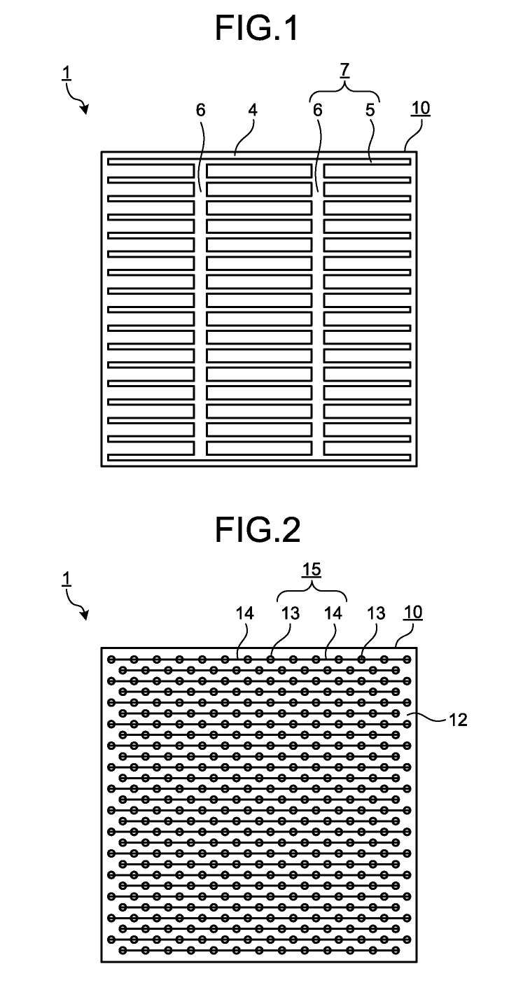

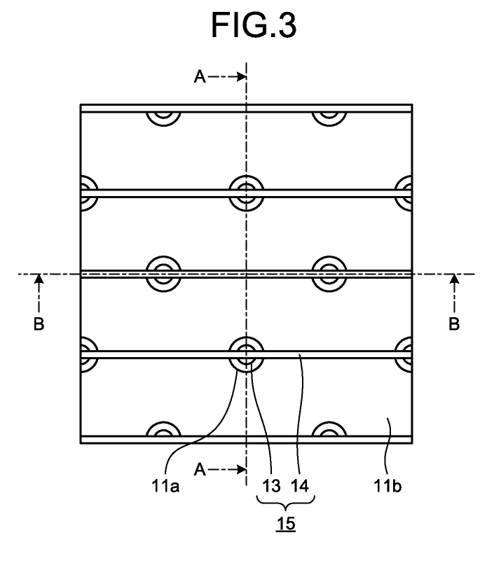

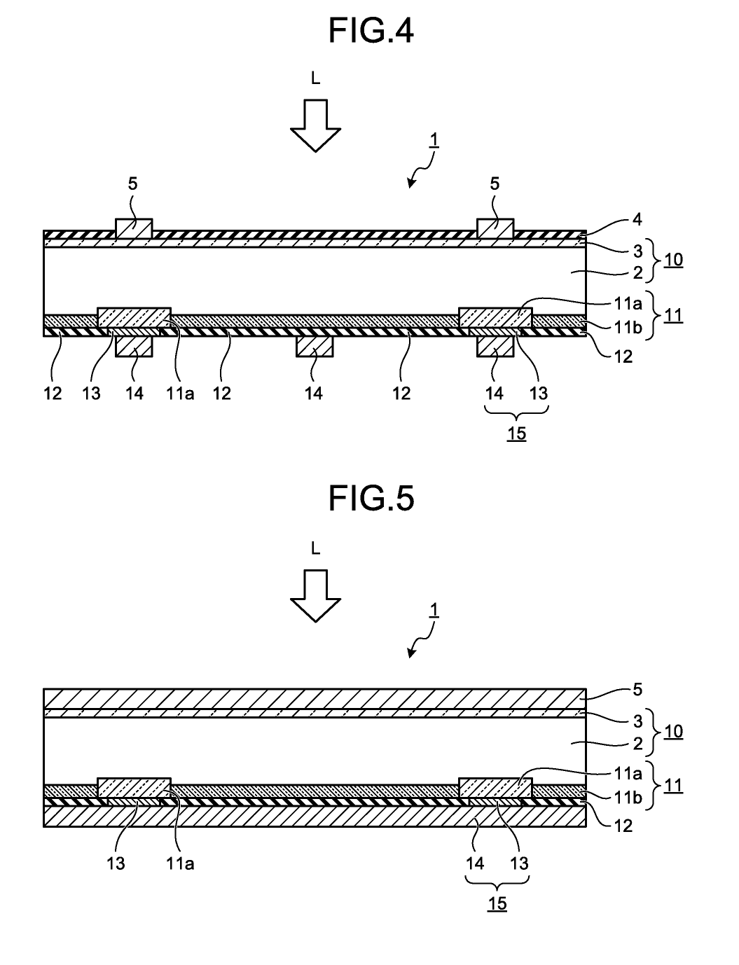

FIG. 1 is a top view of a solar cell 1 according to a first embodiment of the present invention, as viewed from a light-receiving surface side. FIG. 2 is a bottom view of the solar cell 1 according to the first embodiment of the present invention, as viewed from a back surface side opposite to the light-receiving surface. FIG. 3 is an enlarged view illustrating the back surface side of the solar cell 1 according to the first embodiment of the present invention. FIG. 4 is a cross-sectional view of a main part of the solar cell 1 according to the first embodiment of the present invention, and is a cross-sectional view taken along a line A-A in FIG. 3. FIG. 5 is a cross-sectional view of a main part of the solar cell 1 according to the first embodiment of the present invention, and is a cross-sectional view taken along a line B-B in FIG. 3. Note that FIG. 3 illustrates a state seen through a back surface side insulating film 12.

In the solar cell 1 according to the present embodiment, boron (B) is diffused in the whole of a light-receiving surface of an n-type semiconductor substrate 2 made of an n-type silicon material to form a p-type light-receiving surface side impurity diffusion layer 3, and thereby a semiconductor substrate 10 having a p-n junction is formed. In the first embodiment, the n-type semiconductor substrate 2 is a substrate made of a single crystal silicon material. Hereinafter, the n-type semiconductor substrate 2 may be referred to as an n-type silicon substrate 2 in some cases. By using the n-type silicon substrate 2 with a long minority carrier lifetime for a solar cell substrate, it is possible to obtain higher photoelectric conversion efficiency as compared with a case of using a p-type silicon substrate for a solar cell substrate. The impurity concentration of the p-type light-receiving surface side impurity diffusion layer 3 is set to about 5×10¹⁹ atoms/cm³ or less. A lower limit of the impurity concentration of the p-type light-receiving surface side impurity diffusion layer 3 is about 1×10¹⁷ atoms/cm³ from the viewpoint of an electrical conductivity of a surface.

On the light-receiving surface side impurity diffusion layer 3, an antireflection film 4 is formed, which is made of a silicon nitride film that serves as an insulating film. The antireflection film 4 has an antireflection function of preventing reflection on the light-receiving surface of the solar cell 1 and also a function as a light-receiving surface side passivation film that passivates the light-receiving surface of the semiconductor substrate 10, that is, the light-receiving surface of the solar cell 1. In the solar cell 1, light L is incident from a side of the antireflection film 4.

As the semiconductor substrate 2, an n-type single crystal silicon substrate or an n-type polycrystalline silicon substrate can be used. As the antireflection film 4, a silicon oxide film may be used. On a surface on the light-receiving surface side of the semiconductor substrate 10 of the solar cell 1, minute unevenness (not illustrated) is formed as a texture structure. The minute unevenness has a structure which increases an area for absorbing light from the outside on the light-receiving surface, reduces the reflectance on the light-receiving surface, and confines the light.

On the light-receiving surface side of the semiconductor substrate 10, multiple elongated light-receiving surface side grid electrodes 5 are arranged in juxtaposition along a direction of a pair of opposed sides of the semiconductor substrate 10. Multiple light-receiving surface side bus electrodes 6 conducting to the light-receiving surface side grid electrodes 5 are arranged in juxtaposition along a direction of the other pair of opposed sides of the semiconductor substrate 10 in a state where the electrodes 6 are orthogonal to the light-receiving surface side grid electrodes 5. The light-receiving surface side grid electrodes 5 and the light-receiving surface side bus electrodes 6 each are electrically connected to the p-type light-receiving surface side impurity diffusion layer 3 on their respective bottom surface portions. The light-receiving surface side grid electrodes 5 and the light-receiving surface side bus electrodes 6 are each formed of an electrode material containing silver. The light-receiving surface side grid electrodes 5 and the light-receiving surface side bus electrodes 6 constitute a light-receiving surface side electrode 7 that is a first electrode having a comb shape.

The light-receiving surface side electrode 7 is formed of an electrode material containing silver (Ag), aluminum (Al), and glass, and is provided to penetrate the antireflection film 4 and to be electrically connected to the p-type light-receiving surface side impurity diffusion layer 3. The light-receiving surface side electrode 7 is an Ag—Al paste electrode formed by printing and firing an Ag—Al paste that is an electrode material containing silver (Ag), aluminum (Al), and glass.

Since the solar cell 1 according to the first embodiment uses the n-type silicon substrate 2, an emitter layer thereof is the p-type light-receiving surface side impurity diffusion layer 3 that is a p+ layer. Since the solar cell 1 uses the Ag—Al paste electrode as the light-receiving surface side electrode 7, a good contact can be formed between the light-receiving surface side electrode 7 and the p-type light-receiving surface side impurity diffusion layer 3 even in the p-type light-receiving surface side impurity diffusion layer 3 having a relatively low impurity concentration of about 5×10¹⁹ atoms/cm³ or less.

Each light-receiving surface side grid electrode 5 has a width of, for example, about 40 μm to 70 μm, and 100 to 300 light-receiving surface side grid electrodes 5 are arranged in parallel to each other at a predetermined interval and collect electricity generated inside the semiconductor substrate 10. Each light-receiving surface side bus electrode 6 has a width of, for example, about 0.5 mm to 1.0 mm, and two to five light-receiving surface side bus electrodes 6 are arranged per one solar cell and take the electricity collected by the light-receiving surface side grid electrodes 5 to the outside.

On the other hand, the back surface side insulating film 12 is formed on the entire back surface of the semiconductor substrate 10 opposite to the light-receiving surface. The back surface side insulating film 12 is made of a silicon nitride film that is an insulating film. The back surface side insulating film 12 functions as a back surface side passivation film which passivates the back surface of the solar cell 1. Note that a silicon oxide film may be used as the back surface side insulating film 12.

On the back surface of the semiconductor substrate 10 opposite to the light-receiving surface, multiple dot-shaped back surface first electrodes 13 are arranged in a lattice pattern and embedded in the back surface side insulating film 12. The back surface first electrodes 13 are first electrodes on the back surface side, and penetrate the back surface side insulating film 12 to reach back surface side high-concentration impurity diffusion layers 11a on the back surface of the semiconductor substrate 10, which will be described later. The dot-shaped back surface first electrodes 13 are regularly arranged in a predetermined direction on the entire back surface of the semiconductor substrate 10. The back surface first electrodes 13 are arranged in a pattern similar to an arrangement pattern of the back surface side high-concentration impurity diffusion layers 11a. A shape of the dot has a circular shape smaller than a shape of the dot of the back surface side high-concentration impurity diffusion layer 11a. The back surface first electrode 13 is included in the back surface side high-concentration impurity diffusion layer 11a in a plane direction of the semiconductor substrate 10. Therefore, the back surface first electrode 13 is formed like a point on the back surface side high-concentration impurity diffusion layer 11a on the back surface of the semiconductor substrate 10, and is connected to the back surface side high-concentration impurity diffusion layer 11a.

The arrangement pattern of the back surface first electrodes 13 is not limited to the lattice pattern, and may be any pattern as long as the back surface first electrodes 13 are evenly arranged on the entire back surface of the semiconductor substrate 10. In the first embodiment, a shape of the dot is a circular shape. However, as long as the back surface first electrode 13 can be electrically connected to the back surface side high-concentration impurity diffusion layer 11a described later, the dot shape is not limited thereto, but may be an arbitrary shape such as a quadrangular shape.

Furthermore, on the back surface of the semiconductor substrate 10, a number of back surface second electrodes 14 are formed. The back surface second electrodes 14 are second electrodes on the back surface side, and electrically connect the back surface first electrodes 13 to each other. The back surface second electrodes 14 are arranged in juxtaposition on the back surface first electrodes 13 and the back surface side insulating film 12 along a predetermined direction while being in contact with a top portion of each of the back surface first electrodes 13 and a surface of the back surface side insulating film 12. Each of the back surface second electrodes 14 passes over a center of each of the back surface first electrodes 13 arranged along a predetermined direction and electrically connects the back surface first electrodes 13 to each other. Note that each of the back surface second electrodes 14 may be displaced from the center of the back surface first electrode 13 as long as the back surface second electrodes 14 can electrically connect the back surface first electrodes 13 arranged along the predetermined direction, to each other. Then, the back surface first electrodes 13 and the back surface second electrode 14 constitute a back surface side electrode 15.

The back surface first electrode 13 is Ag paste electrode formed by printing and firing an Ag paste that is an electrode material containing silver, a glass or ceramic component, and a solvent, and having a fire-through property, that is, a property of causing fire-through, at the time of firing. The metal included in the back surface first electrodes 13 is not limited to Ag, but may be a metal material which can erode a silicon surface on the back surface of the semiconductor substrate 10 and make electrical contact with the silicon surface when the Ag paste is fired through.

The back surface second electrode 14 is an electrode made of an electrode material which does not have a fire-through property at the time of firing and does not positively make electrical contact with silicon.

The back surface second electrode 14 may be a paste electrode made of an electrode material which has a composition of silver, a glass or ceramic component, and a solvent, the composition being different from that of the back surface first electrodes 13, and has a property such that although fire-through is performed thereon at the time of firing, the amount of erosion on the silicon surface is small and there occurs less damage on the silicon surface. In this case, the metal contained in the back surface second electrodes 14 is not limited to Ag, but may be any metal material as long as it is a metal material which provides a less amount of erosion on the silicon surface on the back surface of the semiconductor substrate 10 and less electrical contact with the silicon surface when performing fire-through at the time of firing of the paste.

When the back surface second electrode 14 is in contact with the silicon surface, the back surface second electrode 14 is in contact with a back surface side low-concentration impurity diffusion layer 11b in addition to the back surface side high-concentration impurity diffusion layer 11a described later. When the back surface second electrode 14 is in contact with the back surface side low-concentration impurity diffusion layer 11b, the recombination at the contact portion is increased, whereas the back surface side low-concentration impurity diffusion layer 11b has a weak electric field effect, and the contact between the back surface second electrode 14 and the back surface side low-concentration impurity diffusion layer 11b has a significant influence, thereby leading to deterioration in the characteristics of the solar cell 1. For this reason, the back surface second electrode 14 is preferably not in contact with the back surface side low-concentration impurity diffusion layer 11b as a result of the fire-through, and even in a case where the back surface second electrode 14 is in contact with the back surface side low-concentration impurity diffusion layer 11b as a result of the fire-through, the caused electrical contact is preferably as small as possible. Therefore, the back surface second electrodes 14 are preferably Ag paste electrodes formed by printing and firing an electrode material paste having no fire-through property, that is, having a property of anti-fire-through, at the time of firing.

An n-type back surface side impurity diffusion layer 11 that is an impurity diffusion layer on the back surface side is formed on a surface layer of the back surface opposite to the light-receiving surface of the semiconductor substrate 10. The n-type back surface side impurity diffusion layer 11 is an n-type impurity diffusion layer in which phosphorus (P) is diffused as an n-type impurity into the entire surface layer of the back surface of the semiconductor substrate 10. In the solar cell 1, two types of layers are formed as the n-type back surface side impurity diffusion layer 11 to form a selective diffusion layer structure. That is, in a surface layer portion on the back surface side of the semiconductor substrate 10, the back surface side high-concentration impurity diffusion layer 11a is formed in a region under each back surface first electrode 13 and a peripheral region thereof. The back surface side high-concentration impurity diffusion layers 11a are first impurity diffusion layers on the back surface side into which phosphorus is diffused at a relatively high concentration in the n-type back surface side impurity diffusion layer 11. The concentration of phosphorus in each back surface side high-concentration impurity diffusion layer 11a is about 1×10²⁰ atoms/cm³.

In a region where the back surface side high-concentration impurity diffusion layer 11a is not formed in the surface layer portion on the back surface side of the semiconductor substrate 10, the back surface side low-concentration impurity diffusion layer 11b is formed. The back surface side low-concentration impurity diffusion layer 11b is a second impurity diffusion layer on the back surface side, into which phosphorus is diffused at a relatively low concentration in the n-type back surface side impurity diffusion layer 11. The concentration of phosphorus in the back surface side low-concentration impurity diffusion layer 11b is about 1×10¹⁹ atoms/cm³. Therefore, in the surface layer portion on the back surface side of the semiconductor substrate 10, the n-type impurity diffusion layer is placed, which includes the back surface side high-concentration impurity diffusion layers 11a and the back surface side low-concentration impurity diffusion layer 11b. The back surface side high-concentration impurity diffusion layers 11a are the first impurity diffusion layers containing phosphorus at a first concentration. The back surface side low-concentration impurity diffusion layer 11b is the second impurity diffusion layer containing phosphorus at a second concentration lower than the first concentration.

To each of the back surface side high-concentration impurity diffusion layers 11a, the dot-shaped back surface first electrode 13 penetrating the back surface side insulating film 12 is connected. Therefore, the back surface side high-concentration impurity diffusion layers 11a are arranged in a pattern similar to the arrangement pattern of the back surface first electrodes 13. That is, the back surface side high-concentration impurity diffusion layers 11a are regularly arranged in a predetermined direction on the entire back surface of the semiconductor substrate 10, and are arranged in a lattice pattern. A shape of the dot is a circular shape. The arrangement pattern of the back surface side high-concentration impurity diffusion layers 11a is not limited to the lattice pattern, and may be any pattern similar to a pattern of the back surface first electrodes 13 as long as the back surface side high-concentration impurity diffusion layers 11a are evenly arranged on the entire back surface of the semiconductor substrate 10. In the first embodiment, the dot is in a circular shape. However, as long as the back surface side high-concentration impurity diffusion layer 11a can be electrically connected to the back surface first electrode 13, the dot shape is not limited thereto, and may be an arbitrary shape such as a quadrangular shape.

The back surface side high-concentration impurity diffusion layer 11a is a low-resistance diffusion layer having a lower electric resistance than the back surface side low-concentration impurity diffusion layer 11b. The back surface side low-concentration impurity diffusion layer 11b is a high-resistance diffusion layer having a higher electric resistance than the back surface side high-concentration impurity diffusion layer 11a. The back surface side impurity diffusion layer 11 is constituted by the back surface side high-concentration impurity diffusion layers 11a and the back surface side low-concentration impurity diffusion layer 11b.

Therefore, when the diffusion concentration of phosphorus in the back surface side high-concentration impurity diffusion layers 11a is set as a first diffusion concentration and the diffusion concentration of phosphorus in the back surface side low-concentration impurity diffusion layer 11b is set as a second diffusion concentration, the second diffusion concentration is lower than the first diffusion concentration. When an electric resistance value of the back surface side high-concentration impurity diffusion layers 11 is set as a first electric resistance value and an electric resistance value of the back surface side low-concentration impurity diffusion layer 11b is set as a second electric resistance value, the second electric resistance value is larger than the first electric resistance value.

In the above-described solar cell 1, the dot-shaped n-type back surface side high-concentration impurity diffusion layers 11a, each of which is a selective diffusion layer region, are formed on the back surface side of the n-type silicon substrate 2. In the solar cell 1, the n-type back surface side low-concentration impurity diffusion layer 11b having a lower impurity concentration than the back surface side high-concentration impurity diffusion layer 11a is formed on the entire surface of the region on the back surface side of the n-type silicon substrate 2 except for the back surface side high-concentration impurity diffusion layers 11a. The n-type back surface side low-concentration impurity diffusion layer 11b has an effect of improving the photoelectric conversion efficiency of the solar cell 1 by minimizing recombination on the back surface of the semiconductor substrate 10 based on a BSF effect and improving an open voltage.

In the above-described solar cell 1, the back surface side insulating film 12 having a function as a passivation film is formed on an outer surface of the n-type back surface side impurity diffusion layer 11 on the back surface side, that is, on an outer surface of the back surface side high-concentration impurity diffusion layers 11a and an outer surface of the back surface side low-concentration impurity diffusion layer 11b. For this reason, the solar cell 1 has an effect of minimizing recombination on the back surface of the semiconductor substrate 10 is improved based on the passivation effect of the back surface side insulating film 12, and accordingly further improving the open voltage to further improve photoelectric conversion efficiency.

In the above-described solar cell 1, the antireflection film 4 also having a function as a passivation film is formed on an outer surface of the p-type light-receiving surface side impurity diffusion layer 3. For this reason, the solar cell 1 has an advantage of improving a minimization effect of recombination on the light-receiving surface of the semiconductor substrate 10 based on the passivation effect of the antireflection film 4, and further improving the open voltage to further improve the photoelectric conversion efficiency.

That is, since the solar cell 1 includes the passivation films on the light-receiving surface and the back surface, high photoelectric conversion efficiency can be obtained.

In the above-described solar cell 1, the concentration of phosphorus in the back surface side high-concentration impurity diffusion layer 11a is about 1×10²⁰ atoms/cm³, and a good contact with a low contact resistance can be formed at an electrical junctions between the back surface side high-concentration impurity diffusion layer 11a and the back surface first electrode 13. Therefore, the solar cell 1 has an advantage of reducing the contact resistance between the back surface side high-concentration impurity diffusion layer 11a and the back surface first electrode 13, and improving an FF (Fill Factor) to further improve the photoelectric conversion efficiency.

In the above-described solar cell 1, the back surface side high-concentration impurity diffusion layers 11a are formed in multiple dots, and the multiple dot-shaped back surface first electrode 13 is formed in an area included in an area of the back surface side high-concentration impurity diffusion layer 11a in a plane direction of the semiconductor substrate 10. That is, the solar cell 1 has a point contact structure in which the back surface first electrode 13 is point-connected to the back surface of the semiconductor substrate 10. The back surface side electrode 15 is not in contact with a region between the back surface first electrodes 13 adjacent to each other in the n-type back surface side impurity diffusion layer 11. That is, the back surface first electrodes 13 adjacent to each other are electrically connected to each other by the back surface second electrode 14 on the back surface side insulating film 12. Therefore, the adjacent back surface first electrodes 13 are electrically connected to each other by the back surface second electrode 14 while being separated from the back surface side impurity diffusion layer 11.

By this configuration, as compared with a case where the back surface side high-concentration impurity diffusion layer and the back surface side electrode are formed in a continuous elongated shape, an area ratio of the back surface side high-concentration impurity diffusion layers 11a in the n-type back surface side impurity diffusion layer 11 can be largely reduced in the solar cell 1. By reducing the area ratio of the back surface side high-concentration impurity diffusion layers 11a in the n-type back surface side impurity diffusion layer 11, an area ratio of the back surface side low-concentration impurity diffusion layer 11b having a large effect of minimizing recombination based on the passivation effect can be increased, and an effect of improving the photoelectric conversion efficiency can be obtained.

In addition, by reducing the area ratio of the back surface side high-concentration impurity diffusion layers 11a in the n-type back surface side impurity diffusion layer 11, the contact region of each back surface first electrode 13 with respect to the back surface side impurity diffusion layer 11 can be largely reduced in the solar cell 1 as compared with a case where the back surface side high-concentration impurity diffusion layer and the back surface side electrode are formed in an elongated shape. Furthermore, by reducing an area of each back surface side high-concentration impurity diffusion layer 11a, an area of each back surface side high-concentration impurity diffusion layer 11a protruding from the corresponding back surface first electrode 13, which hinders improvement of the high photoelectric conversion efficiency because of remarkable recombination, can be reduced in the solar cell 1, and thereby an effect of improving the photoelectric conversion efficiency can be obtained.

In the above-described solar cell 1, the back surface second electrodes 14 each of which electrically connects the back surface first electrodes 13 to each other are formed on the back surface side insulating film 12 and on the back surface first electrodes 13. That is, since the back surface second electrodes 14 are formed without firing-through the back surface side insulating film 12, the back surface second electrodes 14 and the back surface side low-concentration impurity diffusion layer 11b are not electrically connected. In addition, since the back surface second electrodes 14 are formed without firing-through the back surface side insulating film 12, it is advantageously impossible to reduce the passivation effect on the surface of the back surface side low-concentration impurity diffusion layer 11b caused by the back surface side insulating film 12. Therefore, in the solar cell 1, a high passivation effect by the back surface side insulating film 12 can be obtained.

In the above-described solar cell 1, since each back surface second electrode 14 electrically connects the back surface first electrodes 13 to each other, currents which have been collected from the back surface side high-concentration impurity diffusion layers 11a to the back surface first electrodes 13 can be collected. Then, the currents can be taken out of the solar cell 1 by connecting a tab (not illustrated) to the back surface second electrode 14.

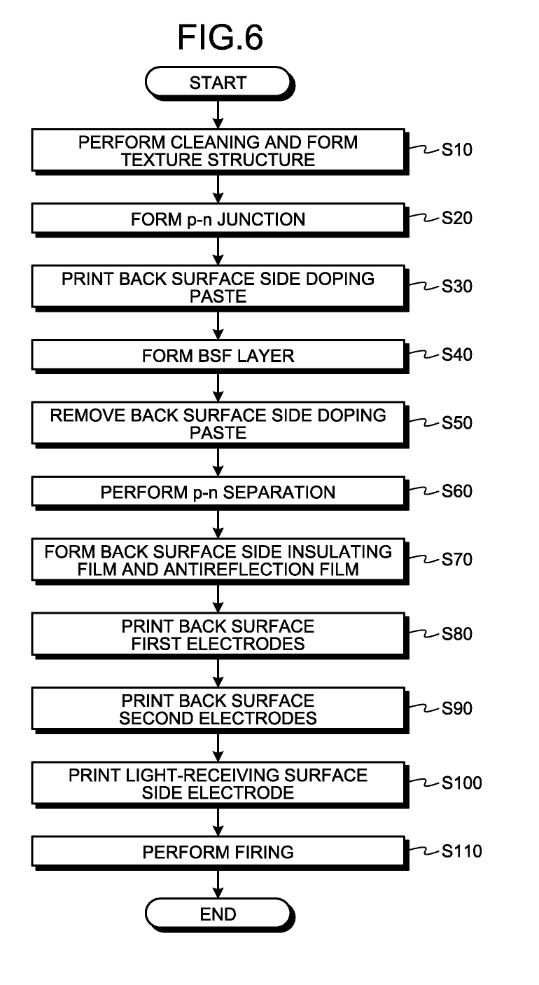

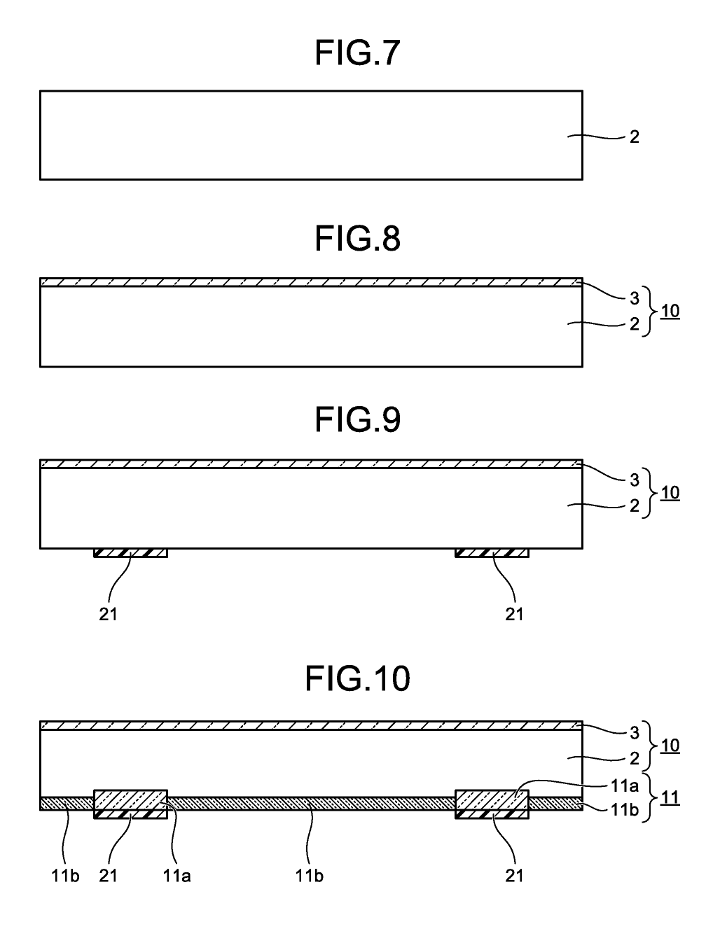

Next, a method of manufacturing the solar cell 1 according to the first embodiment will be described with reference to FIGS. 6 to 12. FIG. 6 is a flowchart for explaining a procedure of the method of manufacturing the solar cell 1 according to the first embodiment of the present invention. FIGS. 7 to 15 are main-part cross-sectional views for explaining the method of manufacturing the solar cell 1 according to first embodiment of the present invention. Note that FIGS. 7 to 15 are main-part cross-sectional views corresponding to FIG. 4.

FIG. 7 is an explanatory view of Step S10 of FIG. 6. In Step S10, the n-type silicon substrate 2 is prepared as the semiconductor substrate 2, cleaning is performed thereon, and a texture structure is formed. Since the n-type silicon substrate 2 is manufactured by cutting and slicing a single crystal silicon ingot obtained in a single crystal pulling step into pieces with desired size and thickness using a cutting device such as a band saw or a multi-wire saw, a damaged layer caused at the time of slicing is left behind on a surface of the substrate 2. Therefore, the surface of the n-type silicon substrate 2 is etched in order also to remove the damaged layer, and thereby cleaning is performed to remove surface contamination caused at the time of the slicing and the damaged layer caused at the time of cutting out the silicon substrate and existing near the surface of the n-type silicon substrate 2. The cleaning is performed by immersing the n-type silicon substrate 2 in an alkaline solution containing about 1 wt % to 10 wt % sodium hydroxide dissolved therein, for example.

Then, after the removal of the damaged layer, fine irregularities are formed on a surface of a first main surface to be the light-receiving surface of the n-type silicon substrate 2, thereby forming the texture structure. The fine irregularities are very minute, and therefore are not expressed as a concavo-convex shape in FIGS. 7 to 15. In order to form the texture structure, for example, a chemical solution is used which is obtained by mixing an additive such as isopropyl alcohol or caprylic acid in an alkaline solution of about 0.1 wt % to 10 wt %. By immersing the n-type silicon substrate 2 in such a chemical solution, the surface of the n-type silicon substrate 2 is etched to obtain the texture structure on the entire surface of the n-type silicon substrate 2. The texture structure may be formed not only on the light-receiving surface of the n-type silicon substrate 2 but also on the back surface of the n-type silicon substrate 2. The removal of the surface contamination and damaged layer caused at the time of the slicing and the formation of the texture structure may be performed at the same time.

Next, the surface of the n-type silicon substrate 2 having the texture structure formed thereon is cleaned. For cleaning the surface of the n-type silicon substrate 2, for example, a cleaning method called RCA clean is used. In the RCA clean, a mixed solution of sulfuric acid and hydrogen peroxide, a hydrofluoric acid aqueous solution, a mixed solution of ammonia and hydrogen peroxide, and a mixed solution of hydrochloric acid and hydrogen peroxide are prepared as cleaning solutions, and an organic material, metal, and an oxide film are removed by combining cleaning processes using these cleaning solutions.

Alternatively, without using all types of the above-mentioned cleaning solutions, cleaning processes using one or more of the above-mentioned cleaning solutions may be combined. Besides the above-described cleaning solutions, a mixed solution of hydrofluoric acid and a hydrogen peroxide solution, and water containing ozone may be included as cleaning solutions.

FIG. 8 is an explanatory view of Step S20 of FIG. 6. Step S20 corresponds to a process of forming the p-type light-receiving surface side impurity diffusion layer 3 on the surface of the n-type silicon substrate 2 to form a p-n junction. Formation of the p-type light-receiving surface side impurity diffusion layer 3 is realized by charging the n-type silicon substrate 2 having the texture structure formed thereon into a thermal diffusion furnace and performing a heat treatment of the n-type silicon substrate 2 in the presence of boron tribromide (BBr₃) vapor or in the presence of boron trichloride (BCl₃) vapor. As a result, the semiconductor substrate 10 is obtained in which the p-n junction is formed by the n-type silicon substrate 2 made of an n-type single crystal silicon material and the p-type light-receiving surface side impurity diffusion layer 3 formed on the light-receiving surface side of the n-type silicon substrate 2.

Next, an n-type impurity is diffused into the back surface of the semiconductor substrate 10, that is, the back surface of the n-type silicon substrate 2, and thereby a selective diffusion layer is formed. Here, description is given for a case of using a phosphorus diffusion step with a doping paste for forming the back surface side high-concentration impurity diffusion layers 11a and phosphorus oxychloride (POCl₃) for forming the back surface side low-concentration impurity diffusion layer 11b, as an example.

FIG. 9 is an explanatory view of Step S30 of FIG. 6. Step S30 corresponds to a process of selectively printing a back surface side doping paste 21 containing phosphorus, as a doping paste that is a diffusion source of the n-type impurity, on the back surface of the semiconductor substrate 10, that is, the back surface of the n-type silicon substrate 2. Here, the back surface side doping paste 21 which is a resin paste containing phosphorus oxide is selectively printed as a doping paste on the back surface of the n-type silicon substrate 2 by using a screen printing method. The printed pattern of the back surface side doping paste 21 is a pattern in which multiple dots are arranged in a lattice pattern on the entire back surface of the n-type silicon substrate 2 and is a region serving as a region where the back surface first electrodes 13 are formed on the back surface of the n-type silicon substrate 2 and peripheral regions thereof.

The printed pattern of the back surface side doping paste 21 is configured to have a pattern having an area to the extent that a problem due to excessively high contact resistance between the back surface side high-concentration impurity diffusion layer 11a formed in the same pattern as the printed pattern of the back surface side doping paste 21 and the back surface first electrode 13 does not arise. In addition, the printed pattern of the back surface side doping paste 21 is configured to have a pattern in which dots are regularly arranged in a predetermined direction on the back surface of the n-type silicon substrate 2 at intervals to the extent that there is no problem of deterioration of the characteristics of the solar cell 1 due to increased resistance loss in the n-type silicon substrate 2 resulting from an increased area of each back surface side high-concentration impurity diffusion layer 11a having high electric resistance in the n-type back surface side impurity diffusion layer 11. The printed pattern of the back surface side doping paste 21 is set so as to reduce the area ratio as much as possible, on the back surface of the n-type silicon substrate 2. The printed pattern of the back surface side doping paste 21 is configured to have, for example, a pattern in which dots having a diameter of about 50 μm to 300 μm are arranged in a staggered or lattice pattern at an interval of about 0.3 mm to 3 mm. After printing the back surface side doping paste 21, the back surface side doping paste 21 is dried.

FIG. 10 is an explanatory view of Step S40 of FIG. 6. Step S40 corresponds to a process of forming a BSF layer having a selective diffusion layer structure by heat-treating the semiconductor substrate 10 having the back surface side doping paste 21 printed thereon. In Step S40, the semiconductor substrate 10 having the back surface side doping paste 21 printed thereon is charged into the thermal diffusion furnace and a heat treatment is performed thereon in the presence of phosphorus oxychloride (POCl₃) vapor.

Specifically, a boat on which the semiconductor substrate 10 is placed is charged into a horizontal furnace, and the semiconductor substrate 10 is heat-treated for 30 minutes at about 1000° C. to 1100° C. By this heat treatment, phosphorus which is a dopant component in the back surface side doping paste 21 thermally diffuses into the n-type silicon substrate 2 immediately beneath the back surface side doping paste 21. As a result, the back surface side high-concentration impurity diffusion layers 11a are formed on a surface layer of the back surface of the n-type silicon substrate 2 immediately below the back surface side doping paste 21. The back surface side high-concentration impurity diffusion layers 11a are formed in a pattern in which the back surface side high-concentration impurity diffusion layers 11a are arranged in a staggered or lattice pattern, which is the same as the printed pattern of the back surface side doping paste 21.

On the other hand, the dopant component of the back surface side doping paste 21 is not diffused into regions other than the regions immediately below the back surface side doping paste 21 in the surface layer on the back surface side of the n-type silicon substrate 2. However, phosphorus of the phosphorus oxychloride (POCl₃) vapor is thermally diffused into the surface layer of the regions other than the regions immediately beneath the back surface side doping paste 21 in the surface layer on the back surface side of the n-type silicon substrate 2. Then, the back surface side low-concentration impurity diffusion layer 11b into which phosphorus is diffused at a uniform concentration in a plane direction of the n-type silicon substrate 2 is formed by gas phase diffusion. As a result, there is formed the n-type back surface side impurity diffusion layer 11 having the back surface side high-concentration impurity diffusion layers 11a and the back surface side low-concentration impurity diffusion layer 11b, which is a BSF layer having a selective diffusion layer structure.

The method for forming the back surface side impurity diffusion layer 11 having the selective diffusion layer structure is not limited to the above-described method, that is a method in which the doping paste and thermal diffusion from the gas phase are combined. For example, another method may be used such as a method in which a uniform n-type impurity diffusion layer is formed in gas phase thermal diffusion and then an oxide film that is formed at the time of diffusion and contains an impurity elemental component is locally irradiated with a laser beam, a method in which a uniform n-type impurity diffusion layer is formed in gas phase thermal diffusion, then a mask is formed on a part of the back surface of the n-type silicon substrate 2, and an etching process is performed on the substrate 2, or a method in which an impurity is ion-implanted in the back surface of the n-type silicon substrate 2 using a mask.

Here, in order to prevent the light-receiving surface side of the semiconductor substrate 10 from being directly exposed to the atmosphere within the thermal diffusion furnace, two semiconductor substrates 10 are stacked in a manner such that their light-receiving surface sides are opposed to each other, and charged in the boat. As a result, formation of a phosphorus glass film on the light-receiving surface side of each semiconductor substrate 10 is largely restricted. As a result, phosphorus is prevented from being mixed from the atmosphere in the furnace to the inside of the n-type silicon substrate 2 through the light-receiving surface side of the semiconductor substrate 10. That is, diffusion of phosphorus into the semiconductor substrate 10 is selectively performed in the back surface, and the n-type back surface side impurity diffusion layer 11 is formed on the back surface. A diffusion mask film made of an oxide film or the like may be formed on the light-receiving surface side of the semiconductor substrate 10.

Next, in Step S50 of FIG. 6, the back surface side doping paste 21 is removed. The removal of the back surface side doping paste 21 can be performed by immersing the semiconductor substrate 10 in a hydrofluoric acid aqueous solution. At that time, the oxide film containing phosphorus formed on the surface of the semiconductor substrate 10 in Step S40 is also removed.

Next, a p-n separation process is performed in Step S60 of FIG. 6. In the p-n separation process, the p-type light-receiving surface side impurity diffusion layer 3 formed on the light-receiving surface side of the semiconductor substrate 10 and the n-type back surface side impurity diffusion layer 11 formed on the back surface side of the semiconductor substrate 10 are electrically separated from each other. More specifically, end face etching is performed, in which for example, about 50 to 300 semiconductor substrates 10 which have undergone the processes up to Step S50 are stacked and side surface portions thereof are subjected to an etching process based on plasma discharge. Alternatively, laser separation may be performed, in which a portion in the vicinity of the side end portion on the light-receiving surface side or the back surface side of the semiconductor substrate 10 or a portion of the side surface of the semiconductor substrate 10 is melted by laser irradiation to expose the n-type silicon substrate 2.

In the above description, the preferable methods for performing the p-n separation have been described. However, the p-n separation process of Step S60 can be omitted depending on the separation condition between the p-type light-receiving surface side impurity diffusion layer 3 and the back surface side impurity diffusion layer 11, that is, the magnitude of a leak current, or the arrangement of solar battery cells in a solar cell module which will be a final power generation product.

Next, a silicon oxide film formed on a surface on the light-receiving surface side of the semiconductor substrate 10, that is, a surface of the p-type light-receiving surface side impurity diffusion layer 3 is removed by using, for example, a 5% to 25% hydrofluoric acid aqueous solution. Then, the hydrofluoric acid aqueous solution adhering to the surface of the semiconductor substrate 10 is removed by cleaning with water. At that time, an oxide film formed by cleaning with water, generally called a natural oxide film, may be used as a passivation layer described later or a part thereof. An oxide film formed by cleaning the semiconductor substrate 10 with water containing ozone may be used as an antireflection film or passivation layer described later, or a part thereof for the same purpose.

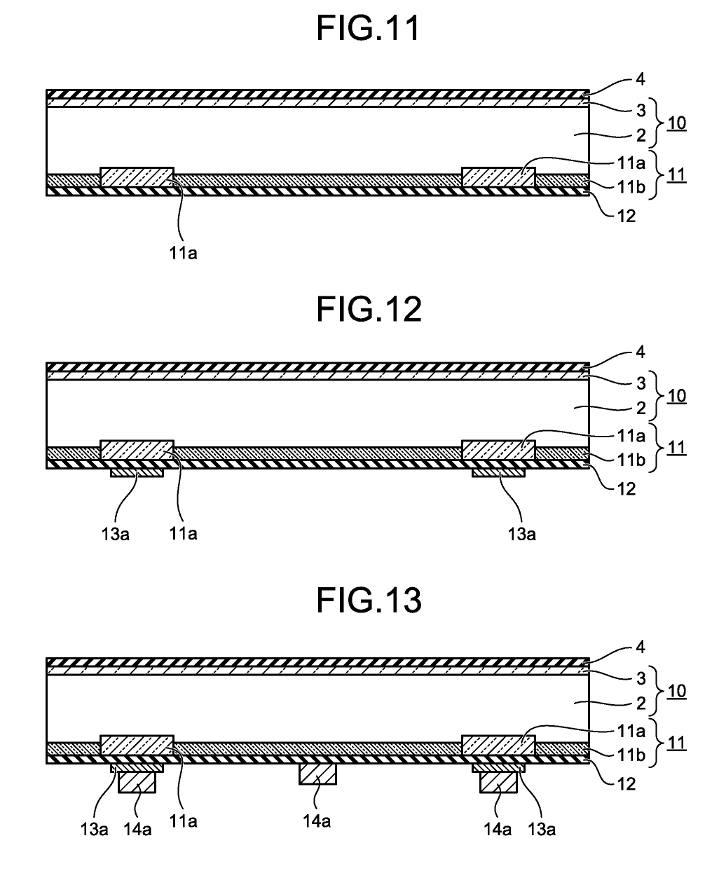

FIG. 11 is an explanatory view of Step S70 of FIG. 6. Step S70 corresponds to a process of forming the back surface side insulating film 12 and the antireflection film 4. First, a silicon nitride film is formed on the back surface of the semiconductor substrate 10, that is, on the back surface side impurity diffusion layer 11 by using, for example, a plasma chemical vapor deposition (CVD) method, and thereby the back surface side insulating film 12 made of an insulating film is formed on the back surface of the semiconductor substrate 10. Another passivation layer may be formed between the silicon nitride film of the back surface side insulating film 12 and the back surface side impurity diffusion layer 11. In that case, the passivation layer is preferably a silicon oxide film, and an oxide film formed by cleaning with water or cleaning with ozone-containing water may be used as described above, in addition to a general thermally-oxidized film.

Subsequently, the antireflection film 4 made of a silicon nitride film is formed by using, for example, plasma CVD, on the light-receiving surface side of the semiconductor substrate 10, that is, on the p-type light-receiving surface side impurity diffusion layer 3. A passivation layer may be further formed between the silicon nitride film of the antireflection film 4 and the p-type light-receiving surface side impurity diffusion layer 3. In that case, the passivation layer is preferably a silicon oxide film or an aluminum oxide film, or a laminated film of a silicon oxide film and an aluminum oxide film. In a case where a silicon oxide film is used for the passivation layer, an oxide film formed by cleaning with water or cleaning with ozone-containing water may be used as described above, in addition to a general thermally-oxidized film. In a case where an aluminum oxide film is used, the aluminum oxide film is formed by, for example, plasma CVD or atomic layer deposition (ALD). In that case, fixed charge contained in a formed film has an effect of enhancing a passivation ability, which is more preferable.

The order of formation of other passivation layers of front and back surfaces of the back surface side insulating film 12, the antireflection film 4, and the semiconductor substrate 10 is not necessarily limited to the above-mentioned order, and an order other than the above-mentioned order may be appropriately adopted to form the layers.

FIG. 12 is an explanatory view of Step S80 of FIG. 6. Step S80 corresponds to a process of printing the back surface first electrodes 13. In Step S80, an Ag-containing paste 13a, which is an electrode material paste containing Ag, glass frit, and a solvent, is selectively printed by screen printing on a region above each back surface side high-concentration impurity diffusion layer 11a on the back surface side insulating film 12 on the back surface of the semiconductor substrate 10. The Ag-containing paste 13a is an electrode material paste having a property of causing fire-through and capable of making electrical contact with the silicon surface on the back surface of the semiconductor substrate 10.

The Ag-containing paste 13a is printed on a region included in each back surface side high-concentration impurity diffusion layer 11a in a pattern in which multiple dots are arranged in a lattice pattern on the entire surface of the back surface side insulating film 12. The printed pattern of the Ag-containing paste 13a is, for example, configured to be a pattern in which dots having a diameter of about 30 μm to 150 μm are arranged in a staggered or lattice pattern at an interval of about 0.5 mm to 3.0 mm. Thereafter, the Ag-containing paste 13a is dried, and thereby the back surface first electrodes 13 in a dry state are formed.

FIG. 13 is an explanatory view of Step S90 of FIG. 6. Step S90 corresponds to a process of printing the back surface second electrodes 14. In Step S90, an Ag paste 14a which is an electrode material paste having no fire-through property is selectively printed by screen printing on a top portion of each of the back surface first electrodes 13 in a dry state and the surface of the back surface side insulating film 12 between the back surface first electrodes 13 in a dry state.

The Ag paste 14a is printed in juxtaposition along a predetermined direction in a pattern which connects the back surface first electrodes 13 in a dry state to each other. The printed pattern of the Ag paste 14a is a linear pattern having a width of about 20 μm to 200 μm, for example. Thereafter, the Ag paste 14a is dried, and thereby the back surface second electrodes 14 in a dry state are formed.

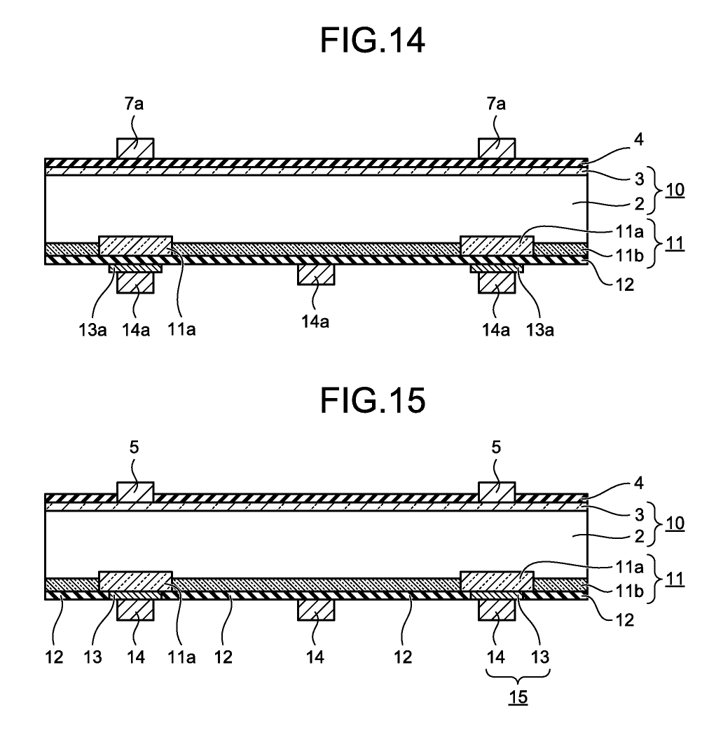

FIG. 14 is an explanatory view of Step S100 of FIG. 6. Step S100 corresponds to a process of printing the light-receiving surface side electrode 7. In Step S100, an Ag—Al-containing paste 7a, which is an electrode material paste containing Ag, Al, glass frit, and a solvent, for example, is selectively printed by screen printing on the antireflection film 4 in a shape of the light-receiving surface side grid electrodes 5 and the light-receiving surface side bus electrodes 6. Thereafter, the Ag—Al-containing paste 7a is dried, and thereby the light-receiving surface side electrode 7 in a dry state having a comb shape is formed.

FIG. 15 is an explanatory view of Step S110 of FIG. 6. Step S110 corresponds to a process of simultaneously firing the electrode material pastes printed and dried on the light-receiving surface side and the back surface side of the semiconductor substrate 10. Specifically, the semiconductor substrate 10 is introduced into a firing furnace, and subjected to a short-time heat treatment at a peak temperature of about 600° C. to 900° C., for example, 800° C., for 3 seconds in the air atmosphere. By doing so, a resin component in each electrode material paste disappears. Then, on the light-receiving surface side of the semiconductor substrate 10, while a glass material contained in the Ag—Al-containing paste 7a melts and penetrates the antireflection film 4, a silver material is brought into contact with silicon of the p-type light-receiving surface side impurity diffusion layer 3 and resolidifies. As a result, the light-receiving surface side grid electrodes 5 and the light-receiving surface side bus electrodes 6 are obtained, and electrical continuity between the light-receiving surface side electrode 7 and the silicon of the semiconductor substrate 10 is secured.

On the back surface side of the semiconductor substrate 10, while the glass material contained in the Ag-containing paste 13a melts and penetrates the back surface side insulating film 12, a silver material is brought into contact with the silicon of each back surface side high-concentration impurity diffusion layer 11a and resolidifies. As a result, the back surface first electrodes 13 are obtained. Furthermore, the Ag paste 14a is connected to the back surface first electrodes 13. As a result, the back surface second electrodes 14 which connect the back surface first electrodes 13 to each other are obtained, and electrical continuity between the back surface side electrodes 15 and the silicon of the semiconductor substrate 10 is secured. The electrode material pastes may be fired separately for the light-receiving surface side and the back surface side.

The solar cell 1 according to the first embodiment illustrated in FIGS. 1 to 5 can be manufactured by carrying out the above processes. The order of arrangement of the pastes as electrode materials on the semiconductor substrate 10 may be permutated between the light-receiving surface side and the back surface side.

As described above, in the solar cell 1 according to the first embodiment, a solar cell is achieved which has a low area ratio of the back surface side high-concentration impurity diffusion layers 11a in the back surface side impurity diffusion layer 11 and a small contact region between the back surface side impurity diffusion layer 11 and the back surface side electrodes 15, and is capable of increasing photoelectric conversion efficiency. Therefore, the solar cell 1 according to the first embodiment has an effect of providing a solar cell that has a selective diffusion layer structure and can achieve high photoelectric conversion efficiency.

### Second Embodiment

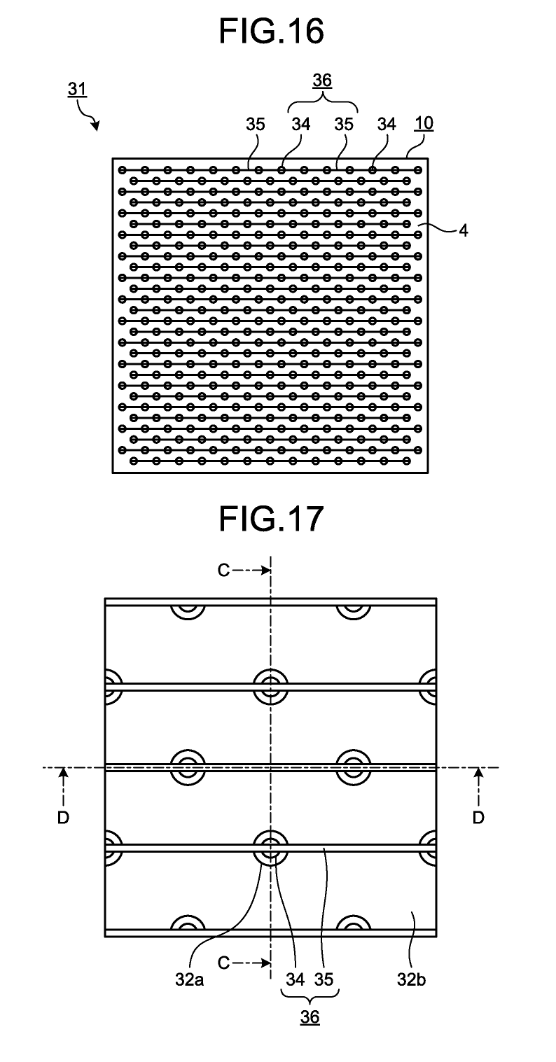

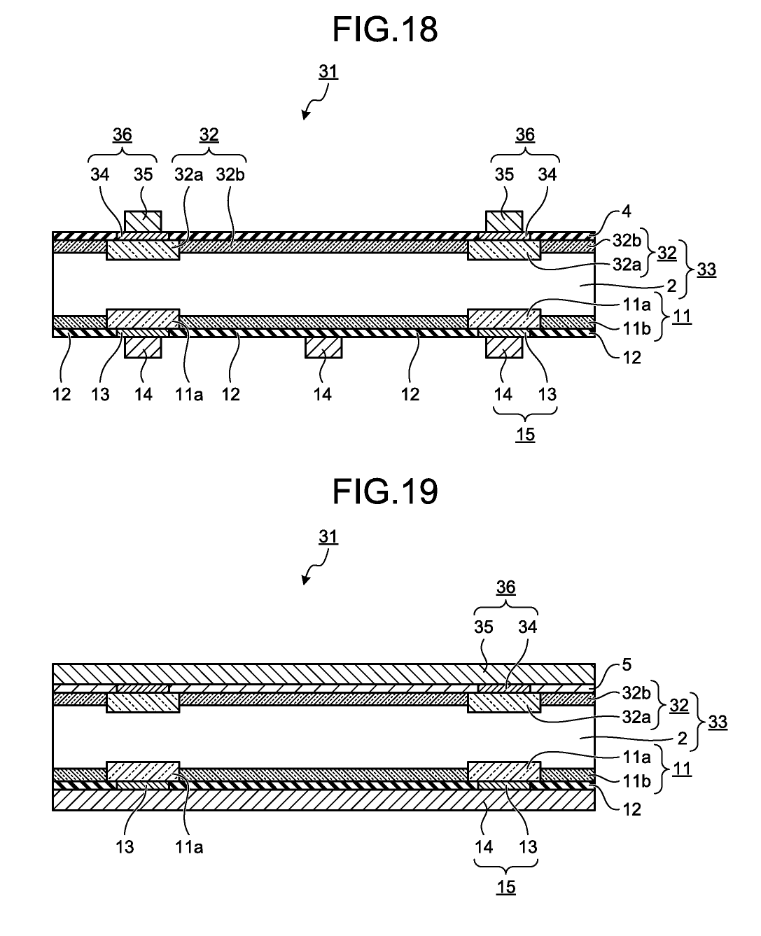

FIG. 16 is a top view of a solar cell 31 according to a second embodiment of the present invention, as viewed from a light-receiving surface side. FIG. 17 is an enlarged view illustrating the light-receiving surface side of the solar cell 31 according to the second embodiment of the present invention. FIG. 18 is a main-part cross-sectional view of the solar cell 31 according to the second embodiment of the present invention, and is a cross-sectional view taken along a line C-C in FIG. 17. FIG. 19 is a main-part cross-sectional view of the solar cell 31 according to the second embodiment of the present invention, and is a cross-sectional view taken along a line D-D in FIG. 17. FIG. 17 illustrates a state of the solar cell 31 seen through the antireflection film 4.

The solar cell 31 according to the second embodiment is different from the solar cell 1 according to the first embodiment in the structure on the light-receiving surface side. In the solar cell 31, a p-type light-receiving surface side impurity diffusion layer 32 which is an impurity diffusion layer on the light-receiving surface side has a selective diffusion layer structure similarly to the n-type back surface side impurity diffusion layer 11 of the solar cell 1, and a light-receiving surface side electrode 36 has a configuration similar to that of the back surface side electrode 15 of the solar cell 1. The configuration of the back surface side of the solar cell 31 is similar to that of the solar cell 1 according to the first embodiment. The same reference signs as those of the solar cell 1 are given to the same members as those of the solar cell 1, and thereby descriptions thereof will be omitted.

In the solar cell 31 according to the second embodiment, the p-type light-receiving surface side impurity diffusion layer 32 into which boron (B) is diffused is formed on the entire light-receiving surface of the n-type semiconductor substrate 2, and thereby a semiconductor substrate 33 having a p-n junction is formed. In the solar cell 31, two types of layers are formed for the p-type light-receiving surface side impurity diffusion layer 32 to form a selective diffusion layer structure. That is, in a surface layer portion on the light-receiving surface side of the semiconductor substrate 33, a light-receiving surface side high-concentration impurity diffusion layer 32a is formed in a region under each light-receiving surface first electrode 34 described later and a peripheral region thereof. The light-receiving surface side high-concentration impurity diffusion layers 32a are first impurity diffusion layers on the light-receiving surface side into which boron is diffused at a relatively high concentration in the p-type light-receiving surface side impurity diffusion layer 32. The concentration of boron in each light-receiving surface side high-concentration impurity diffusion layer 32a is about 1×10²⁰ atoms/cm³.

In a region where no light-receiving surface side high-concentration impurity diffusion layer 32a is formed in the surface layer portion on the light-receiving surface side of the semiconductor substrate 33, a light-receiving surface side low-concentration impurity diffusion layer 32b is formed. The light-receiving surface side low-concentration impurity diffusion layer 32b is a second impurity diffusion layer on the light-receiving surface side into which boron is diffused at a relatively low concentration in the p-type light-receiving surface side impurity diffusion layer 32. The concentration of boron in the light-receiving side low-concentration impurity diffusion layer 32b is about 5×10¹⁹ atoms/cm³. Therefore, a p-type impurity diffusion layer having a third impurity diffusion layer containing boron at a third concentration and a fourth impurity diffusion layer containing boron at a fourth concentration lower than the third concentration is arranged in the surface layer portion on the light-receiving surface side of the semiconductor substrate 33.

To each of the light-receiving surface side high-concentration impurity diffusion layers 32a, the dot-shaped light-receiving surface first electrode 34 is connected. The light-receiving surface first electrode 34 is a first electrode on the light-receiving surface and penetrates the antireflection film 4. Therefore, the light-receiving surface side high-concentration impurity diffusion layers 32a are arranged in a pattern similar to the arrangement pattern of the light-receiving surface first electrodes 34. In addition, the pattern of the light-receiving surface side high-concentration impurity diffusion layers 32a is similar to the pattern of the back surface side high-concentration impurity diffusion layers 11a.

On the light-receiving surface side of the semiconductor substrate 33, the multiple dot-shaped light-receiving surface first electrodes 34 are arranged in a lattice pattern and embedded in the antireflection film 4. The light-receiving surface first electrodes 34 are first electrodes on the light-receiving surface, and penetrate the antireflection film 4 to reach the light-receiving surface side high-concentration impurity diffusion layers 32a. In addition, the pattern of the light-receiving surface first electrodes 34 is similar to the pattern of the back surface first electrodes 13. Therefore, the light-receiving surface first electrodes 34 are formed like points on the light-receiving surface side high-concentration impurity diffusion layers 32a on the light-receiving surface side of the semiconductor substrate 33 and are connected to the light-receiving surface side high-concentration impurity diffusion layers 32a.

Furthermore, on the light-receiving surface side of the semiconductor substrate 33, a plurality of light-receiving surface second electrodes 35 is formed. The light-receiving surface second electrodes 35 are second electrodes on the light-receiving surface and electrically connect the light-receiving surface first electrodes 34 to each other. The light-receiving surface second electrodes 35 are electrodes made of an electrode material which does not have a fire-through property at the time of firing and does not positively make electrical contact with silicon. The light-receiving surface second electrodes 35 are arranged in juxtaposition on the light-receiving surface first electrodes 34 and the antireflection film 4 along a predetermined direction while being in contact with a top portion of each of the light-receiving surface first electrodes 34 and the surface of the antireflection film 4. The light-receiving surface first electrodes 34 and the light-receiving surface second electrode 35 constitute the light-receiving surface side electrode 36.

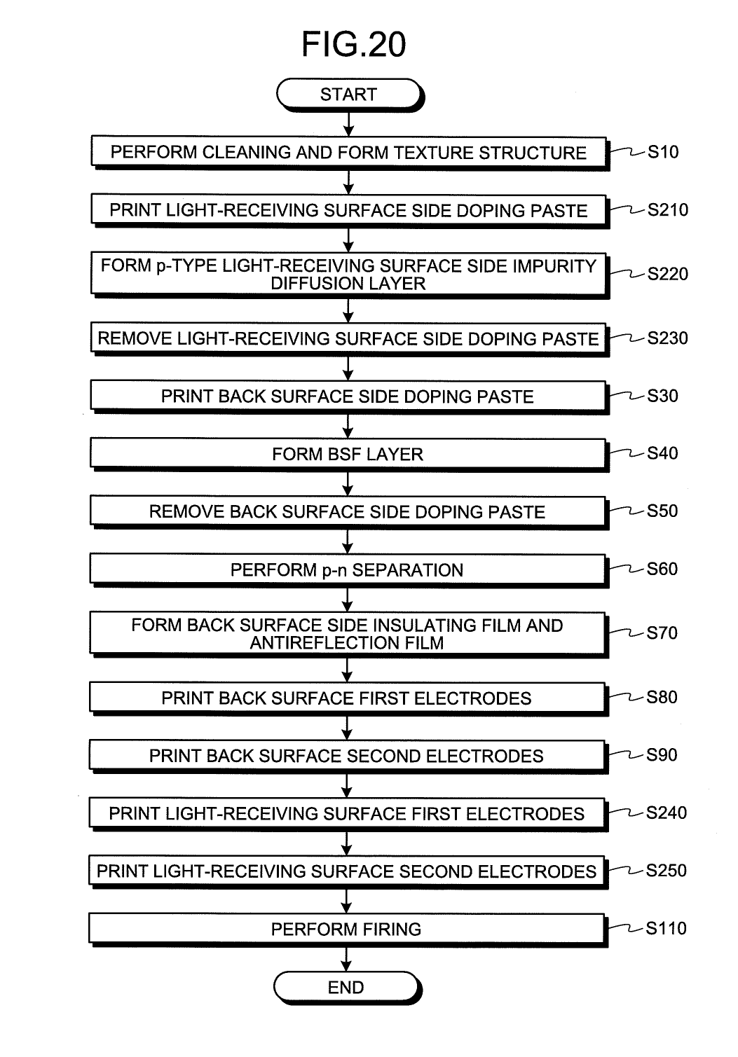

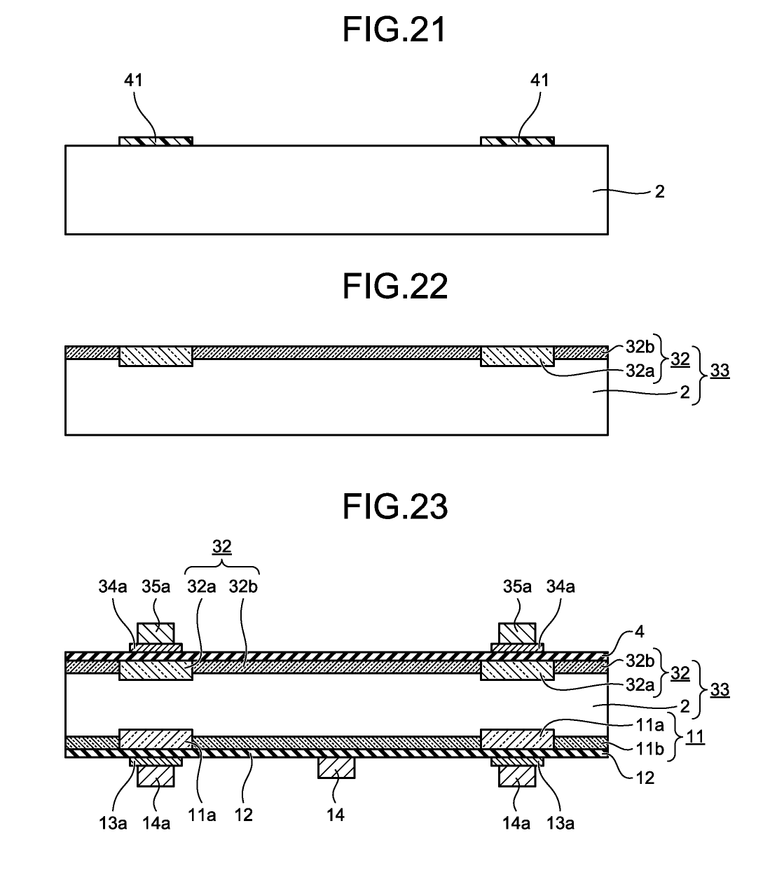

The solar cell 31 according to the second embodiment can be manufactured by forming the p-type light-receiving surface side impurity diffusion layer 32 in a method similar to that for the n-type back surface side impurity diffusion layer 11 of the solar cell 1 according to the first embodiment, and forming the light-receiving surface side electrodes 36 in a method similar to that for the back surface side electrodes 15 of the solar cell 1 according to the first embodiment. With reference to FIGS. 20 to 23, a main procedure of a method of manufacturing the solar cell 31 will be briefly described. FIG. 20 is a flowchart for explaining the procedure of the method of manufacturing the solar cell 31 according to the second embodiment of the present invention. FIGS. 21 to 23 are main-part cross-sectional views for explaining the method of manufacturing the solar cell 31 according to the second embodiment of the present invention. In FIG. 20, to the same flows as those in FIG. 6, the same step numbers are given.

First, after performing Step S10, a light-receiving surface side doping paste 41 containing boron is selectively printed in Step S210 as a doping paste that is a diffusion source of a p-type impurity, on the light-receiving surface side of the n-type silicon substrate 2 as illustrated in FIG. 21. Here, the light-receiving surface side doping paste 41 which is a resin paste containing boron oxide is selectively printed as a doping paste on the light-receiving surface of the n-type silicon substrate 2 using a screen printing method. The printed pattern of the light-receiving surface side doping paste 41 is a pattern in which multiple dots are arranged in a lattice pattern on the entire light-receiving surface of the n-type silicon substrate 2 and corresponds to a region serving as a region where each light-receiving surface first electrode 34 is formed on the light-receiving surface of the n-type silicon substrate 2 and a peripheral region thereof.

Next, in Step S220, the n-type silicon substrate 2 having the light-receiving surface side doping paste 41 printed thereon is heat-treated, thereby forming the p-type light-receiving surface side impurity diffusion layer 32 having a selective diffusion layer structure. In Step S220, the n-type silicon substrate 2 having the light-receiving surface side doping paste 41 printed thereon is charged into a thermal diffusion furnace, and a heat treatment is performed thereon in the presence of boron tribromide (BBr₃) vapor or boron trichloride (BCl₃) vapor.

As a result, the light-receiving surface side high-concentration impurity diffusion layers 32a are formed on a surface layer on the light-receiving surface side of the n-type silicon substrate 2 immediately beneath the light-receiving surface side doping paste 41. On the other hand, the light-receiving surface side low-concentration impurity diffusion layer 32b is formed by gas phase diffusion in a region except for the regions immediately beneath the light-receiving surface side doping paste 41 in the surface layer on the light-receiving surface side of the n-type silicon substrate 2. As a result, as illustrated in FIG. 22, the p-type light-receiving surface side impurity diffusion layer 32 having a selective diffusion layer structure is formed. Then, the semiconductor substrate 33 is obtained in which a p-n junction is formed of the n-type silicon substrate 2 made of n-type single crystal silicon and the p-type light-receiving surface side impurity diffusion layer 32 formed on the light-receiving surface side of the n-type silicon substrate 2.

Next, in Step S230, the light-receiving surface side doping paste 41 is removed in a method similar to that in Step S50.

Next, the processes of Steps S30 to S90 are performed on the semiconductor substrate 33.

Next, in Step S240, the light-receiving surface first electrodes 34 are printed. In Step S240, as illustrated in FIG. 23, an Ag—Al-containing paste 34a, which is an electrode material paste containing Ag, Al, glass frit, and a solvent, is selectively printed by screen printing on a region above each light-receiving surface side high-concentration impurity diffusion layer 32a on the antireflection film 4 on the light-receiving surface of the semiconductor substrate 33. The Ag—Al-containing paste 34a is an electrode material paste that has a property of causing fire-through and can make electrical contact with the silicon surface of the light-receiving surface of the semiconductor substrate 33. Thereafter, the Ag—Al-containing paste 34a is dried, and thereby the light-receiving surface first electrodes 34 in a dry state are formed.

The Ag—Al-containing paste 34a is printed on a region included in each light-receiving surface side high-concentration impurity diffusion layer 32a in a pattern in which multiple dots are arranged in a lattice pattern on the entire surface of the antireflection film 4. In addition, the printed pattern of the Ag—Al-containing paste 34a is similar to the printed pattern of the Ag-containing paste 13a.

Next, in Step S250, the light-receiving surface second electrodes 35 are printed. In Step S250, as illustrated in FIG. 23, an Ag paste 35a which is an electrode material paste having no fire-through property at the time of firing is selectively printed by screen printing on a top portion of each of the light-receiving surface first electrodes 34 in a dry state and the surface of the antireflection film 4 between the light-receiving surface first electrodes 34 in a dry state. The Ag paste 35a is printed in juxtaposition along a predetermined direction in a pattern of connecting the light-receiving surface first electrodes 34 in a dry state to each other. In addition, the printed pattern of the Ag paste 35a is similar to the printed pattern of the Ag paste 14a. Thereafter, the Ag paste 35a is dried, and thereby the light-receiving surface second electrodes 35 in a dry state are formed.

Thereafter, in Step S110, the electrode material pastes printed and dried on the light-receiving surface side and the back surface side of the semiconductor substrate 33 are simultaneously fired. As a result, on the back surface side of the semiconductor substrate 33, the back surface side electrodes 15 each having the back surface first electrodes 13 and the back surface second electrode 14 are obtained.

On the other hand, on the light-receiving surface side of the semiconductor substrate 33, while a glass material contained in the Ag—Al-containing paste 34a melts and penetrates the antireflection film 4, the Ag—Al material is brought into contact with silicon of each light-receiving surface side high-concentration impurity diffusion layer 32a and resolidifies. As a result, the light-receiving surface first electrodes 34 are obtained. Furthermore, the Ag paste 35a is connected to the light-receiving surface first electrodes 34. By so doing, the light-receiving surface second electrode 35 which connects the light-receiving surface first electrodes 34 to each other is obtained, and electrical continuity between the light-receiving surface side electrodes 36 and the silicon of the semiconductor substrate 33 is secured. As a result, the light-receiving surface side electrodes 36 each having the light-receiving surface first electrodes 34 and the light-receiving surface second electrode 35 are obtained. Note that the electrode material pastes may be fired separately for the light-receiving surface side and the back surface side.

The solar cell 31 according to the second embodiment illustrated in FIGS. 16 to 19 can be manufactured by carrying out the above-described processes. The order of arrangement of the pastes as electrode materials on the semiconductor substrate 33 may be permutated between the light-receiving surface side and the back surface side.

In the solar cell 31 according to the second embodiment as described above, the p-type light-receiving surface side impurity diffusion layer 32 has a selective diffusion layer structure similarly to the n-type back surface side impurity diffusion layer 11 of the solar cell 1 according to the first embodiment, and the light-receiving surface side electrodes 36 each have a similar configuration to that of each back surface side electrode 15 of the solar cell 1 according to the first embodiment. As a result, in the solar cell 31, a similar effect to that of the solar cell 1 according to the first embodiment can be achieved also on the light-receiving surface side thereof.

Therefore, with the solar cell 31 according to the second embodiment, a solar cell is achieved which has a low area ratio of the light-receiving surface side high-concentration impurity diffusion layers 32a in the light-receiving surface side impurity diffusion layer 32 and a small contact region between the light-receiving surface side impurity diffusion layer 32 and the light-receiving surface side electrode 36, and is capable of increasing photoelectric conversion efficiency.

As with the case of the back surface second electrode 14, the light-receiving surface second electrode 35 has a composition of silver, a glass or ceramic component, and a solvent, which is different from that of the light-receiving surface first electrode 34, and may be a paste electrode as an electrode material having a property such that the material experiences fire-through at the time of firing but has a small amount of erosion on the silicon surface thereby leading to less damage on the silicon surface. In that case, the metal contained in the light-receiving surface second electrode 35 is not limited to Ag. Any metal material may be used as long as it is a metal material which provides a less amount of erosion on the silicon surface on the light-receiving surface of the semiconductor substrate 33 and less electrical contact with the silicon surface when experiencing fire-through at the time of firing of the paste.

The configurations described in the embodiments above each show one example of the content of the present invention, and can be combined with other publicly known techniques and partially omitted or modified without departing from the gist of the present invention.

### REFERENCE SIGNS LIST

1, 31 solar cell; 2, 10, 33 semiconductor substrate; 3, 32 light-receiving surface side impurity diffusion layer; 4 antireflection film; 5 light-receiving surface side grid electrode; 6 light-receiving surface side bus electrode; 7, 36 light-receiving surface side electrode; 7a Ag—Al-containing paste; 11 back surface side impurity diffusion layer; 11a back surface side high-concentration impurity diffusion layer; 11b back surface side low-concentration impurity diffusion layer; 12 back surface side insulating film; 13 back surface first electrode; 13a Ag-containing paste; 14 back surface second electrode; 14a, 35a Ag paste; 15 back surface side electrode; 21 back surface side doping paste; 32a light-receiving surface side high-concentration impurity diffusion layer; 32b light-receiving surface side low-concentration impurity diffusion layer; 34 light-receiving surface first electrode; 35 light-receiving surface second electrode; 41 light-receiving surface side doping paste.

1. A solar cell comprising:
an n-type semiconductor substrate having a p-n junction;
an impurity diffusion layer which is formed on a light-receiving surface of the semiconductor substrate or a surface layer on a back surface side opposite to the light-receiving surface, and has a first impurity diffusion layer containing an n-type or p-type impurity element at a first concentration and a second impurity diffusion layer containing an impurity element of the same conductivity type as a conductivity type of the first impurity diffusion layer at a second concentration lower than the first concentration;
first electrodes which are formed at a number of locations on a surface of the semiconductor substrate on which the impurity diffusion layer has been formed, each electrically connected to the first impurity diffusion layer; and
a second electrode which electrically connects the first electrodes while being separated from the impurity diffusion layer.

2. The solar cell according to claim 1, comprising a passivation film formed on the impurity diffusion layer, wherein
the first electrode is embedded in the passivation film, and
the second electrodes are formed on the passivation film and the first electrodes.

3. The solar cell according to claim 1, wherein the first impurity diffusion layer and the first electrodes are formed in dot shapes having a predetermined interval therebetween.

4. The solar cell according to claim 1, comprising:
a p-type light-receiving surface side impurity diffusion layer that is formed on a surface layer on a light-receiving surface side of the semiconductor substrate and contains a p-type impurity element;
a light-receiving surface side passivation film formed on the light-receiving surface side impurity diffusion layer; and
a light-receiving surface side electrode electrically connected to the light-receiving surface side impurity diffusion layer,
wherein the impurity diffusion layer is an n-type back surface side impurity diffusion layer formed on the surface layer on the back surface side of the semiconductor substrate,
the passivation film is a back surface side passivation film, and
the first electrodes and the second electrode correspond to a back surface side electrode electrically connected to the back surface side impurity diffusion layer.

5. The solar cell according to claim 1, comprising:
an n-type back surface side impurity diffusion layer that is formed on the surface layer on the back surface side of the semiconductor substrate and contains an n-type impurity element;
a back surface side passivation film formed on the back surface side impurity diffusion layer; and
a back surface side electrode electrically connected to the back surface side impurity diffusion layer,
wherein the impurity diffusion layer is a p-type light-receiving surface side impurity diffusion layer formed on the surface layer on the light-receiving surface side of the semiconductor substrate,
the passivation film is a light-receiving surface side passivation film, and
the first electrodes and the second electrode correspond to a light-receiving surface side electrode electrically connected to the light-receiving surface side impurity diffusion layer.

6. A method of manufacturing a solar cell, the method comprising:
a first step of forming an impurity diffusion layer having a first impurity diffusion layer in which an n-type or p-type impurity element is diffused at a first concentration, and a second impurity diffusion layer in which an impurity element of the same conductivity type as a conductivity type of the first impurity diffusion layer is diffused at a second concentration lower than the first concentration, on a light-receiving surface of an n-type semiconductor substrate having a p-n junction or a surface layer on a back surface side opposite to the light-receiving surface;
a second step of forming a passivation film on the impurity diffusion layer;
a third step of printing a first electrode paste on the passivation film in a region above the first impurity diffusion layer;
a fourth step of printing a second electrode paste on the first electrode paste; and
a fifth step of simultaneously firing the first electrode paste and the second electrode paste, and forming first electrodes embedded in the passivation film and electrically connected to the first impurity diffusion layer and a second electrode electrically connected to the first electrodes in a state where the second electrode is located away from the impurity diffusion layer.

7. The method of manufacturing a solar cell according to claim 6, wherein
in the fifth step, the second electrode is formed without the second electrode paste being fired through the passivation film.

8. (canceled)

9. The method of manufacturing a solar cell according to claim 6, wherein
in the first step, the first impurity diffusion layers are formed in dot shapes having a predetermined interval therebetween, and
in the fifth step, the first electrodes are formed in dot shapes having a predetermined interval therebetween.

10. The method of manufacturing a solar cell according to claim 9, wherein
the first step comprises:
a sixth step of coating the light-receiving surface of the semiconductor substrate or the surface layer on the back surface side with a doping paste containing an n-type or p-type impurity element; and
a seventh step of forming the first impurity diffusion layer in a region under the doping paste in the semiconductor substrate by subjecting the semiconductor substrate to a heat treatment in a treatment chamber in an atmosphere of a gas containing an impurity element of the same conductivity type as a conductivity type of the doping paste.
